(19) United States
(12) Patent Application Publication
(10) Pub. No.: US 2026/0327781 A1
(43) Pub. Date: Oct. 22, 2026

(54) METHOD FOR IMPROVED INTERCONNECT YIELD

(71) Applicant: Applied Materials, Inc., Santa Clara, CA (US)

(72) Inventor: Zhiyuan Wu, San Jose, CA (US)

(73) Assignee: Applied Materials, Inc., Santa Clara, CA (US)

(21) Appl. No.: 19/643,012

(22) Filed: Apr. 9, 2026

Related U.S. Application Data
(60) Provisional application No. 63/790,360, filed on Apr. 17, 2025.

(51) Int. Cl. C23C 14/14; C23C 14/02; C23C 14/04; H10W 20/00

(52) U.S. Cl. CPC C23C 14/14; C23C 14/022; C23C 14/024; C23C 14/046; H10W 20/035; H10W 20/049; H10W 20/056

(57) ABSTRACT

Methods of manufacturing interconnect structures as part of a microelectronic device fabrication process are described. The methods include filling a gap in a surface of a substrate by forming a barrier/liner layer on dielectric sidewalls of a gap, diffusing at least one of manganese and manganese nitride into the barrier/liner layer, and depositing a metal film to fill the gap.

### CROSS-REFERENCE TO RELATED APPLICATIONS

This application claims priority under 35 U.S.C. § 119(e) to U.S. Provisional Application No. 63/790,360, filed Apr. 17, 2025, the disclosure of which is incorporated herein by reference in its entirety.

### TECHNICAL FIELD

Embodiments of the disclosure generally relate to methods of forming interconnect structures in the manufacture of microelectronic devices. More particularly, embodiments of the disclosure are directed to methods for selectively improving yield of interconnects of microelectronic devices.

### BACKGROUND

Multiple challenges impede power and performance improvements when scaling transistors and interconnects to the 3 nm node, 2 nm node, 1.4 nm node, and beyond. Interconnects include metal lines that transfer current within the same device layer and metal vias that transfer current between layers. Pitch reduction narrows the width of both and increases resistance, and also increases the voltage drop across a circuit, throttling circuit speed and increasing power dissipation.

While transistor performance improves with scaling, the same cannot be said for interconnect metals. As dimensions shrink, interconnect via resistance can increase by a factor of 10. An increase in interconnect via contact resistance may result in resistive-capacitive (RC) delays that reduce performance and increases power consumption. A conventional copper interconnect structure includes a barrier layer and/or a metal liner (barrier/liner) deposited on the sidewalls of a gap that provide a via extending to a metal bottom of the gap. The sidewalls are dielectric material, providing good adhesion and preventing the copper from diffusing into the dielectric layer. Increased via resistance remains an issue, especially in smaller features when barrier layers on sidewalls form an increasing part of the via volume.

In current interconnect manufacturing processes, a surface feature (e.g., a trench or via) is filled with a metal or conductive material in a gap fill process. The gap fill process includes copper reflow. Voids tend to form where the barrier/liner meets the metal bottom of the gap. Accordingly, there is a need for methods for depositing material layers that improve performance of interconnects, for example, reducing via resistance and improving deposition selectivity.

### SUMMARY

One or more embodiments of the disclosure are directed to a method of filling a gap defined by dielectric sidewalls and a metal bottom in a surface of a substrate, the method comprising depositing a self-assembled monolayer on the metal bottom of the gap; depositing a barrier layer on the dielectric sidewalls that extends from a top of the gap to the metal bottom of the gap and does not cover the metal bottom of the gap; depositing a liner layer on the barrier layer to provide a barrier/liner layer; removing the self-assembled monolayer; diffusing at least one of manganese and manganese nitride into the barrier/liner layer; and depositing a metal film to fill the gap.

In some embodiments, the barrier/liner layer extends from the top of the gap to the bottom of the gap, and the at least one of manganese and manganese nitride is diffused into the barrier layer from the top of the gap to the bottom of the gap. In other embodiments, the at least one of the manganese and manganese nitride is diffused into barrier/liner layer at only a portion of the barrier/liner layer adjacent to the metal bottom.

One or more embodiments described herein are used in manufacturing interconnect structures as part of a microelectronic device fabrication process.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a cross-sectional schematic view of a microelectronic device including a gap having sidewalls and a bottom with a barrier/liner layer formed on the sidewalls after removal of a self-assembled monolayer(SAM) in accordance with the prior art;

FIG. 1B illustrates the microelectronic device of FIG. 1B after the gaps has been filled with a metal film in accordance with the prior art;

FIG. 2A illustrates a process flow diagram of a method of manufacturing a microelectronic device in accordance with one or more embodiments of the disclosure;

FIG. 2B illustrates a cross-sectional schematic view of a microelectronic device including a gap having sidewalls and a bottom with a self-assembled monolayer (SAM) formed on the bottom of the gap in accordance with one or more embodiments of the disclosure;

FIG. 2C illustrates a barrier layer selectively deposited on the sidewalls of the gap of FIG. 1B in accordance with one or more embodiments of the disclosure;

FIG. 2D illustrates a metal liner selectively deposited on the barrier layer of FIG. 1C in accordance with one or more embodiments of the disclosure;

FIG. 2E illustrates removal of the self-assembled monolayer (SAM) formed in FIG. 1B in accordance with one or more embodiments of the disclosure and diffusing manganese and/or manganese nitride into the barrier/liner layer;

FIG. 2F illustrates a gap fill process filling the gap of FIG. 2E in accordance with one or more embodiments of the disclosure;

FIG. 2G illustrates removal of the self-assembled monolayer (SAM) formed in FIG. 1B in accordance with one or more embodiments of the disclosure and forming a layer to diffuse manganese and/or manganese nitride into the barrier/liner layer; and

FIG. 2H a gap fill process filling the gap of FIG. 2G in accordance with one or more embodiments of the disclosure.

The Figures are shaded to help identify individual components. The shading is for illustrative purposes only and no particular materials of construction are intended and the scope of the disclosure is not limited to any particular materials of construction absent a clear indication.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

According to one or more embodiments, the term “about” used in connection with a value is inclusive of the stated value and has the meaning dictated by the context. For example, it includes at least the degree of error associated with the measurement of the particular value. One of ordinary skill in the art would understand the term “about” is used herein to mean that an amount of “about” of a recited value produces the desired degree of effectiveness in the device formed and/or methods of the present disclosure. One of ordinary skill in the art would further understand that the metes and bounds of “about” with respect to the value of a percentage, amount or quantity of any component in an embodiment can be determined by varying the value, determining the effectiveness of the method for each value, and determining the range of values that provides methods with the desired degree of effectiveness in accordance with the present disclosure. The term “about” is further used to reflect the possibility that a method may result in trace components of other materials that do not alter the effectiveness or safety of the composition. For example, in some embodiments, “about” means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

In the present disclosure, the term “substantially” refers to a degree of deviation that is sufficiently small so as to not measurably detract from the identified property or circumstance. The exact degree of deviation allowable may in some cases depend on the specific context. The phrase “substantially free” means that the composition excludes any amount more than trace impurities that are not intentionally added by the method, but do not negatively impact the method and the device formed by the method.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the microelectronic device in use or operation in addition to the orientation depicted in the Figures. For example, if the microelectronic device in the Figures is turned over, elements described as “below” or “beneath” other elements would then be oriented “above” the other elements. Thus, the exemplary term “below” may encompass both an orientation of above and below. The microelectronic device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular features, structures, materials, or characteristics are combined in any suitable manner.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate unless the context clearly indicates otherwise. Additionally, reference to “depositing on” or “forming on” a substrate can mean both a bare substrate and a substrate with one or more films or features deposited or formed thereon.

According to one or more embodiments, “substrate,” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. In some embodiments, the semiconductor substrate comprises one or more of doped or undoped crystalline silicon (Si), doped or undoped crystalline silicon germanium (SiGe), doped or undoped amorphous silicon (Si), or doped or undoped amorphous silicon germanium (SiGe). Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

According to one or more embodiments, the term “on” indicates that there is contact between elements. The term “directly on” indicates that there is direct contact between elements with no intervening elements.

According to one or more embodiments, as used herein, the term “in situ” refers to processes that are all performed in the same processing chamber or within different processing chambers that are connected as part of an integrated processing system, such that each of the processes are performed without an intervening vacuum break. According to one or more embodiments, as used herein, the term “ex situ” refers to processes that are performed in at least two different processing chambers such that one or more of the processes are performed with an intervening vacuum break. In some embodiments, processes are performed without breaking vacuum or without exposure to ambient air.

As used herein, the terms “precursor,” “reactant,” “reactive gas,” “reactive species,” and the like are used interchangeably to refer to any gaseous species that can react with the substrate surface.

As used herein, the term “chemical vapor deposition” refers to the exposure of at least one reactive species to deposit a layer of material on the substrate surface. In some embodiments, the chemical vapor deposition (CVD) process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously. As used herein, “substantially simultaneously” means that most of the duration of the first reactive species exposure overlaps with the second reactive species exposure.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the reaction chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

According to one or more embodiments, “cyclical deposition” or “atomic layer deposition” (ALD) refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially. In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

One or more of the layers deposited on the substrate or substrate surface are continuous. According to one or more embodiments, as used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

One or more embodiments of the disclosure provide methods for improving performance of interconnects. Interconnects comprise metal lines that transfer current within the same device layer, and metal vias that transfer current between layers. These lines and vias are formed with a conductive metal such as copper (Cu) or tungsten (W) in gaps formed within the microelectronic device. In one or more embodiments, a dielectric layer comprises at least one feature defining a gap having sidewalls and a bottom. In one or more embodiments, the gap includes the metal lines and the metal vias. In one or more embodiments, the metal lines have a sidewall and a bottom. In one or more embodiments, the metal vias have a sidewall and a bottom. As used in this specification and the appended claims, unless specified otherwise, reference to the “bottom of the gap” is intended to mean the bottom of the metal via, which is nearest the substrate surface.

Embodiments of the disclosure provide methods of manufacturing interconnect structures in the manufacture of microelectronic devices. In one or more embodiments, the microelectronic devices described herein comprise at least one top interconnect structure that is interconnected to at least one bottom interconnect structure. Embodiments of the disclosure provide microelectronic devices and methods of manufacturing microelectronic devices that improve performance of interconnects, for example, reducing via resistance.

Advantageously, by diffusing manganese and/or manganese nitride into at least a portion of the barrier/liner layer after removal of the self-assembled monolayer(SAM) prior to filling a gap enhances adhesion between the barrier/liner layer and the gap fill metal, for example copper. In one or more embodiments, degradation of interconnects is avoided. It was determined that plasma treatment of the dielectric sidewalls and a shadowing effect causes the plasma to effectively remove carbon and oxygen from the dielectric sidewall in the area adjacent to the metal bottom of the gap. In addition, it was determined that the self-assembled monolayer (SAM) that is deposited prior to forming the barrier/liner layer interferes with forming the barrier/liner layer, causing weak adhesion of the barrier/liner layer to the gap fill metal, in particular, copper. Advantageously, by diffusing manganese and/or manganese nitride into the barrier/liner layer improves the gap fill metal film adhesion to the barrier/liner layer and prevent delamination of the gap fill metal, which provides improved yield in the manufacture of microelectronic devices including interconnects. According to one or more embodiments, as used herein, “barrier/liner layer” refers to a composite layer formed by a liner layer deposited on a barrier layer. According to one or more embodiments, as used herein, “diffusing manganese and/or manganese nitride into the barrier/liner layer” may include the manganese and/or manganese nitride being diffused into the barrier layer only or the liner layer only, while in some embodiments, diffusing manganese and/or manganese nitride into the barrier/liner layer” may include the manganese and/or manganese nitride being diffused into the liner layer and the barrier layer that forms the composite barrier/liner layer.

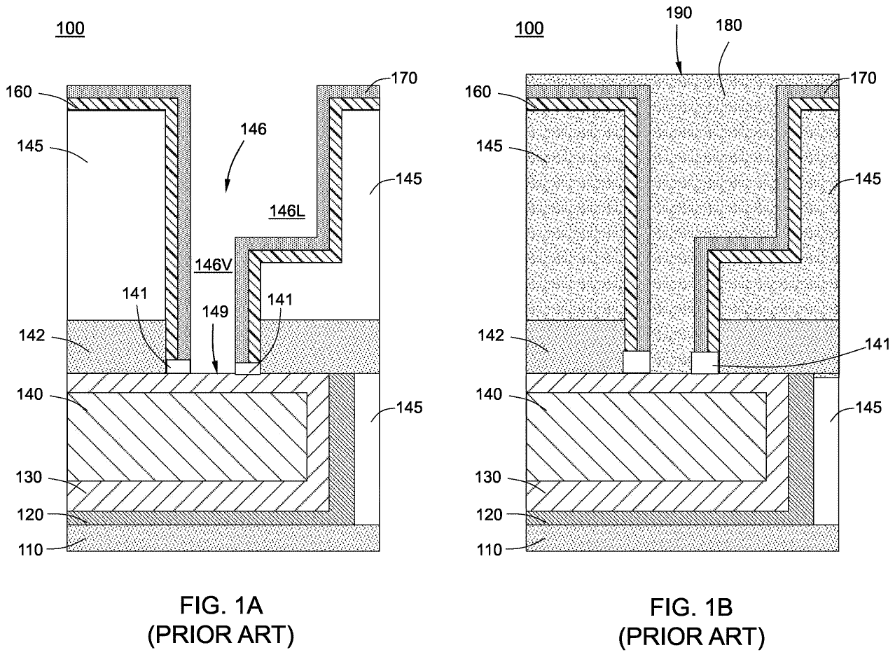

FIGS. 1A and 1B illustrate the problem inherent in the prior art. In FIG. 1A, the microelectronic device 100 comprises the substrate 110, a barrier layer 120 on the substrate 110, a metal layer 130 on the barrier layer 120, a conductive filled gap 140, an aluminum oxide etch stop layer 142, and the dielectric layer 145 on the aluminum oxide etch stop layer 142. The dielectric layer 145 comprises at least one feature defining the gap 146 having sidewalls 148 and the metal. According to one or more embodiments, a self-assembled monolayer (SAM) 150 is formed on the metal bottom 149 of the gap 146. It will be appreciated that in one or more embodiments, the conductive filled gap 140 forms a metal line that transfers current within the same device layer. In one or more embodiments, the SAM 150 is formed on the metal layer 130. In one or more embodiments, the SAM 150 is deposited by exposing the metal bottom 149 of the gap 146 to a hydrocarbon or a silane carried in argon (Ar) gas. In one or more embodiments, the SAM 150 comprises any suitable SAM known to the skilled artisan, for example, an unsaturated hydrocarbon. In some embodiments, the SAM comprises a silane or a hydrocarbon having the formula H−C≡C−R₃, wherein R3 is a linear alkyl chain comprising from 1 to 20 carbon atoms. In other embodiments, the silane has a formula R—SiH₃, wherein R is selected from a linear alkyl chain and a branched alkyl chain comprising from 2 to 20 carbon atoms. The SAM blocks deposition of the barrier layer on the metal bottom of the gap.

In some embodiments, the at least one feature defines a cylindrical via that, when filled with metal, transfers current between layers, and lines that transfer current within the same device layer. In some embodiments, the at least one feature defines the gap 146 in the dielectric layer 145. In some embodiments, the gap 146 defines a via portion 146V and a line portion 146L.

The metal bottom 149 of the gap 146 is defined by the metal layer 130. In one or more embodiments, the metal bottom 149 of the gap 146 and the metal layer 130 comprise the same material. In one or more embodiments, the metal bottom 149 of the gap 146 comprises one or more of ruthenium (Ru), copper (Cu), cobalt (cobalt), molybdenum (Mo), tantalum (Ta), or tungsten (W). In one or more embodiments, the metal bottom 149 of the gap 146 comprises one or more of copper (Cu), cobalt (cobalt), molybdenum (Mo), or tungsten (W).

In one or more embodiments, the self-assembled monolayer (SAM) 150 is formed on the metal bottom 149 of the gap 146 in accordance with operation 13 of the method 10 (FIGS. 1A and 1B). Stated differently, in one or more embodiments, the self-assembled monolayer (SAM) 150 is formed on the metal layer 130, which defines the metal bottom 149 of the gap 146. In one or more embodiments, the portion of the metal layer 130 on which the self-assembled monolayer (SAM) 150 is formed defines the metal bottom 149 of the gap 146. In one or more embodiments, the self-assembled monolayer (SAM) 150 is formed selectively on the metal bottom 149 of the gap 146 by exposing the substrate 110 to a by exposing the metal bottom 149 of the gap 146 to a hydrocarbon or a silane carried in argon (Ar) gas.

As shown in FIGS. 1A and 1B, a barrier layer 160 has been selectively deposited on the sidewalls 148 of the gap 146. In one or more embodiments, the barrier layer 160 has the same properties as the barrier layer 120. In one or more embodiments, the barrier layer 160 does not form on the metal bottom 149 of the gap 146 due to the presence of the self-assembled monolayer (SAM) 150. A liner layer 170 is selectively deposited on the barrier layer. A gap fill material 180 is deposited in the gap 146.

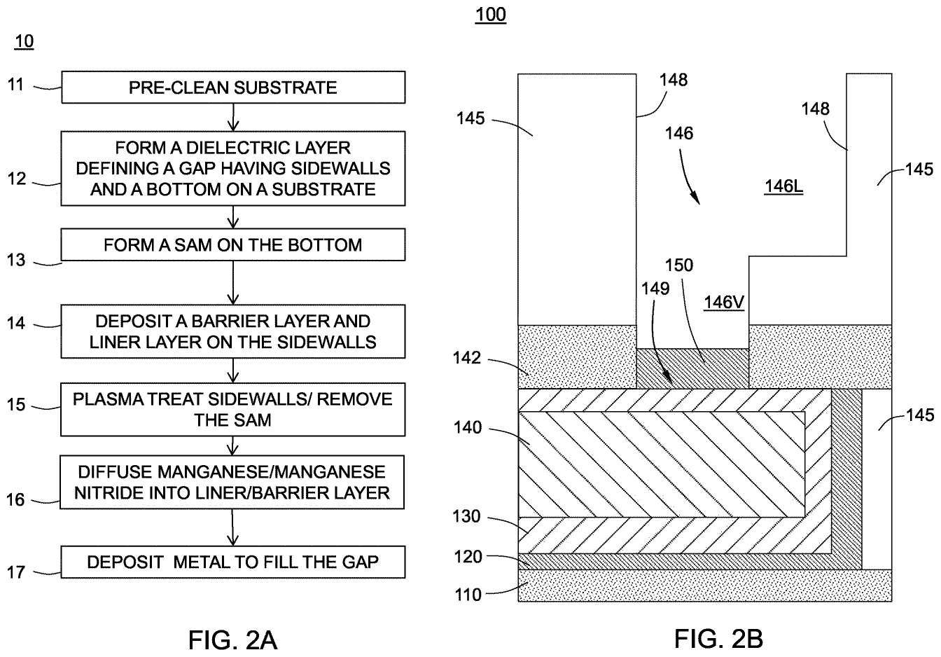

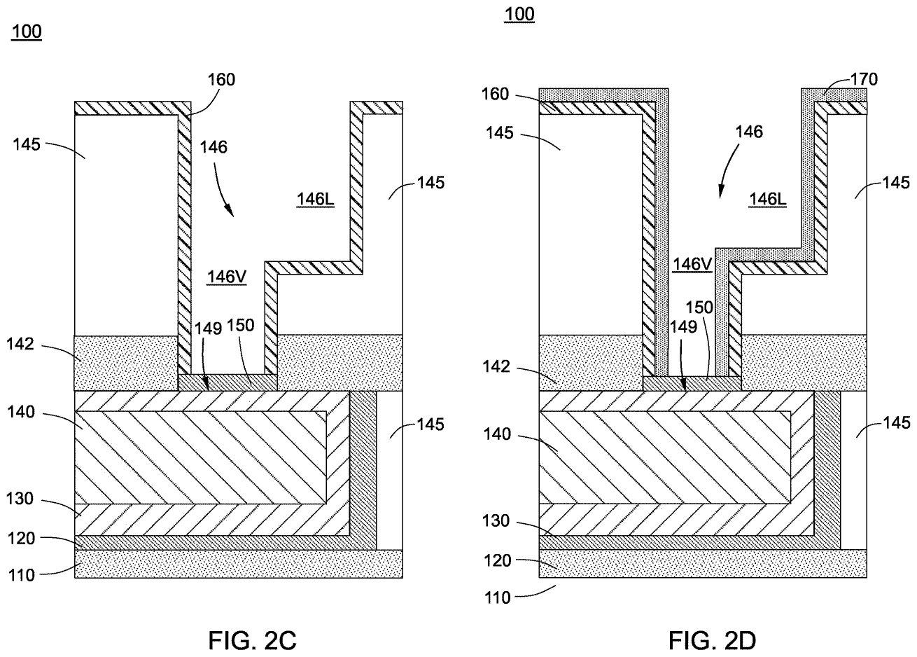

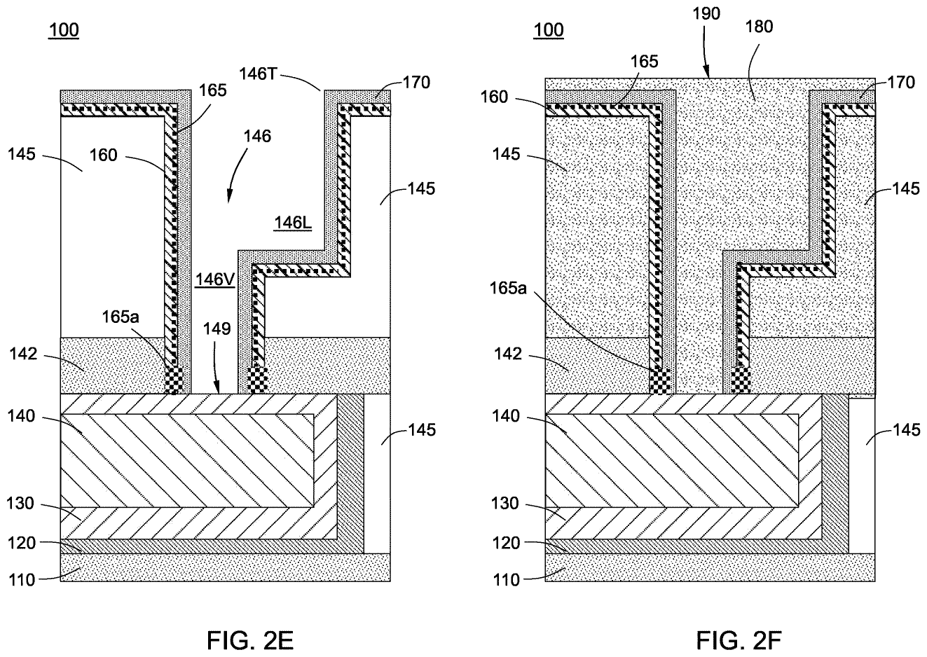

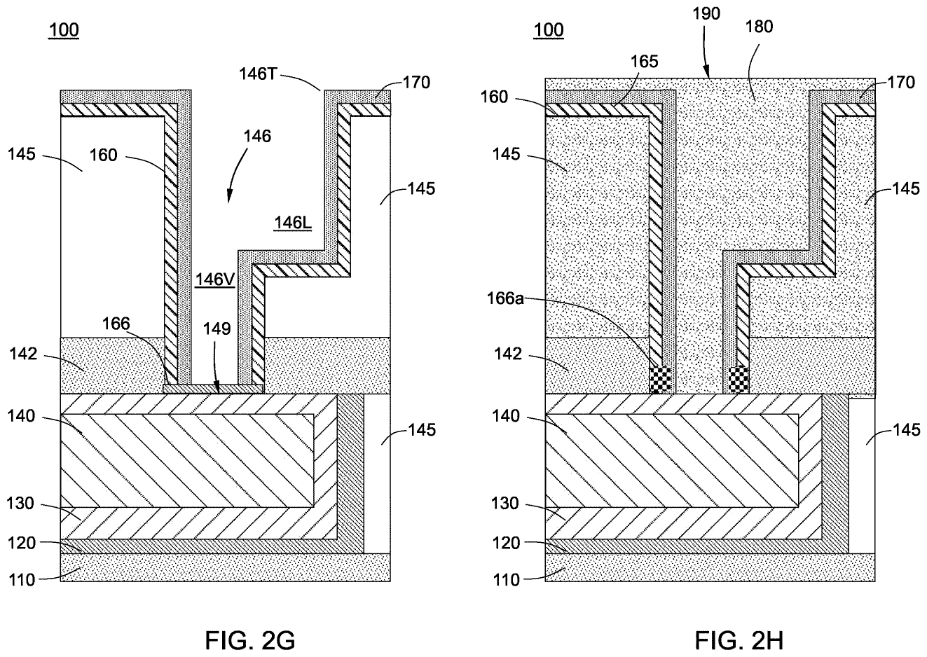

As can be seen in FIG. 1A, the area adjacent to and immediately above the metal bottom 149 has voids 141, which do not contain barrier/liner layer. According to one or more embodiments used herein “barrier/liner layer” (160/170) collectively refers to barrier layer 160 having the liner layer 170 deposited over the barrier layer 160. As described herein, prior to depositing the barrier layer 160 and the liner layer 170, a self-assembled monolayer (described with respect to FIG. 2B) is deposited to prevent deposition of the barrier/liner layer on the metal bottom 149 of the gap 146. When the gap fill material 180 is deposited in the gap, a large void 141 can be formed adjacent to the metal bottom 149. The presence of the void creates an increase in contact resistance, and when this increase in contact resistance is too large, a microelectronic device having a large contact resistance must be rejecting, reducing product yield.

Referring now to FIGS. 2A-F, methods of manufacturing microelectronic devices are illustrated. FIG. 2A is a process flow diagram of an exemplary method 10 of manufacturing a microelectronic device 100. FIG. 2B-F illustrate stages of manufacture of the microelectronic device 100 during the method 10. FIG. 2A is a process flow diagram of an exemplary gap fill method for forming interconnects in a microelectronic device. FIGS. 2B through 2F illustrate stages of manufacture of the microelectronic device during the gap fill method.

The methods, e.g., method 10 and the gap fill method of FIGS. 2A through 2F, generally refer to methods of manufacturing microelectronic devices and more particularly refer to methods of manufacturing interconnect structures as part of a microelectronic device fabrication process. Accordingly, it will be appreciated by the skilled artisan that one or more additional operations needed to complete the fabrication of a microelectronic device are known to the skilled artisan and are within the scope of the present disclosure. The Figures illustrate portions of an electronic device that may or may not be included in the final device formed according the claimed gap fill methods. The skilled artisan will recognize that the embodiments illustrated are exemplary and should not be taken as limiting the scope of the disclosure.

Referring to FIG. 2A, the method 10 optionally comprises, at operation 11, pre-cleaning a substrate 110. In one or more embodiments, keeping the pre-cleaning process under vacuum ensures that no oxide is introduced/formed on the substrate 110 during the method 10. At operation 11, pre-cleaning the substrate 110 removes native oxides from the surface of the substrate 110.

The optional pre-cleaning process of operation 11 can be any suitable process. In some embodiments, the pre-cleaning process of operation 11 removes polymeric residues and oxides from the interconnect and maintains the integrity of the dielectric surface. As used herein, the term “substrate 110” can be used to refer to a substrate and/or a pre-cleaned substrate, unless the context clearly indicates otherwise.

At operation 12, the method 10 comprises forming a dielectric layer on the substrate 110, e.g., the pre-cleaned substrate. The dielectric layer 145 comprises at least one feature defining a gap 146 having sidewalls 148 and a metal bottom 149. At operation 13, the method 10 comprises forming a self-assembled monolayer (SAM) 150 on the metal bottom 149 as described herein. At operation 14, the method 10 comprises selectively depositing a barrier layer 160 and then a metal liner layer 170 on the sidewalls 148. At operation 15, the method 10 comprises removing the self-assembled monolayer (SAM) 150. At operation 16, the method 10 comprises diffusing manganese and/or manganese nitride into the barrier/liner layer. At operation 17, the method 10 comprises performing a gap fill process to fill the gap 146 by depositing a metal film in the gap 146.

In one or more embodiments, the method 10 comprises optional operation 11, operation 12, operation 13, operation 14, operation 15, operation 16, and operation 17. In one or more embodiments, the method 10 consists essentially of optional operation 11, operation 12, operation 13, operation 14, operation 15, operation 16, and operation 17. In one or more embodiments, the method 10 consists of optional operation 11, operation 12, operation 13, operation 14, operation 15, operation 16, and operation 17.

Referring to FIG. 2B-2F, a portion of the microelectronic device 100 is shown during stages of manufacture. In FIG. 2B, the microelectronic device 100 comprises the substrate 110, a barrier layer 120 on the substrate 110, a metal layer 130 on the barrier layer 120, a conductive filled gap 140, an aluminum oxide etch stop layer 142, and the dielectric layer 145 on the aluminum oxide etch stop layer 142. The dielectric layer 145 comprises at least one feature defining the gap 146 having sidewalls 148 and the metal bottom 149. According to one or more embodiments, a self-assembled monolayer (SAM) 150 is formed on the metal bottom 149 of the gap 146. It will be appreciated that in one or more embodiments, the conductive filled gap 140 forms a metal line that transfers current within the same device layer.

In one or more embodiments, the substrate 110 is a wafer, for example, a semiconductor substrate. In one or more embodiments, the substrate 110 is an etch stop layer on a wafer. In one or more embodiments, the substrate 110 is an aluminum oxide etch stop layer on a wafer.

In one or more embodiments, the barrier layer 120 comprises tantalum nitride (TaN). In one or more embodiments, the barrier layer 120 comprises tantalum nitride (TaN) formed by ALD.

In one or more embodiments, the metal layer 130 comprises one or more of ruthenium (Ru), copper (Cu), cobalt (cobalt), molybdenum (Mo), tantalum (Ta), or tungsten (W). In one or more embodiments, the metal layer 130 comprises one or more of copper (Cu), cobalt (cobalt), molybdenum (Mo), or tungsten (W). In one or more embodiments, a portion of the metal layer 130 is etched. In one or more embodiments, the self-assembled monolayer (SAM) 150 is deposited on the portion of the metal layer 130 that is etched. In one or more embodiments, the conductive filled gap 140 comprises one or more of copper (Cu) or cobalt (Co). In one or more embodiments, the etch stop layer 142 comprises one or more of aluminum oxide, silicon nitride, or aluminum nitride.

In one or more embodiments, the dielectric layer 145 comprises a low-κ dielectric material. In one or more embodiments, the dielectric layer 145 comprises silicon oxide (SiOₓ). In one or more embodiments, the dielectric layer 145 comprises SiOₓH_{y}(CH_{z}). Further embodiments provide that the dielectric layer 145 comprises porous or carbon-doped SiOₓ. In some embodiments, the dielectric layer 145 is a porous or carbon-doped SiOₓ layer with a κ value less than about 5. In other embodiments, the dielectric layer 145 is a multilayer structure. For example, in one or more embodiments, the dielectric layer 145 comprises a multilayer structure having one or more of a dielectric layer, an etch stop layer, and a hard mask layer.

In one or more embodiments, the dielectric layer 145 comprises at least one feature defining the gap 146 having sidewalls 148 and the metal bottom 149. The Figures show substrates 110 having a single feature for illustrative purposes; however, those skilled in the art will understand that there can be more than one feature.

Accordding to one or more embodiments, s used herein, the term “feature” means any intentional surface irregularity. Suitable examples of features include but are not limited to trenches which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 5:1, 10:1, 15:1, 20:1, 25:1, 30:1, 35:1 or 40:1.

In some embodiments, the at least one feature defines a cylindrical via that, when filled with metal, transfers current between layers, and lines that transfer current within the same device layer. In some embodiments, the at least one feature defines the gap 146 in the dielectric layer 145. In some embodiments, the gap 146 defines a via portion 146V and a line portion 146L.

The metal bottom 149 of the gap 146 is defined by the metal layer 130. In one or more embodiments, the metal bottom 149 of the gap 146 and the metal layer 130 comprise the same material. In one or more embodiments, the metal bottom 149 of the gap 146 comprises one or more of ruthenium (Ru), copper (Cu), cobalt (cobalt), molybdenum (Mo), tantalum (Ta), or tungsten (W). In one or more embodiments, the metal bottom 149 of the gap 146 comprises one or more of copper (Cu), cobalt (cobalt), molybdenum (Mo), or tungsten (W).

In one or more embodiments, the self-assembled monolayer (SAM) 150 is formed on the metal bottom 149 of the gap 146 in accordance with operation 13 of the method 10 (FIGS. 2A and 2B). Stated differently, in one or more embodiments, the self-assembled monolayer (SAM) 150 is formed on the metal layer 130, which defines the metal bottom 149 of the gap 146. In one or more embodiments, the portion of the metal layer 130 on which the self-assembled monolayer (SAM) 150 is formed defines the metal bottom 149 of the gap 146. In one or more embodiments, the self-assembled monolayer (SAM) 150 is formed selectively on the metal bottom 149 of the gap 146 by exposing the metal bottom 149 of the gap 146 to a hydrocarbon or a silane carried in argon (Ar) gas.

Referring to FIGS. 2A, 2C and 2D, at operation 14 of the method 10, the barrier layer 160 is selectively deposited on the sidewalls 148 of the gap 146 and the metal liner layer 170 is deposited on the barrier layer 160. In one or more embodiments, the barrier layer 160 has the same properties as the barrier layer 120. In one or more embodiments, the barrier layer 160 does not form on the metal bottom 149 of the gap 146 due to the presence of the self-assembled monolayer (SAM) 150.

The barrier layer 160 may be selectively deposited using any suitable deposition technique. In one or more embodiments, the barrier layer 160 is selectively deposited by atomic layer deposition (ALD). The barrier layer 160 may have any suitable thickness. In one or more embodiments, the barrier layer 160 has a thickness in a range of from about 2 Å to about 10 Å. In some embodiments, the barrier layer 160 is deposited in a single ALD cycle. In other embodiments, the barrier layer 160 is deposited in from 1 to 20 ALD cycles. In one or more embodiments, each cycle of the 1 to 20 ALD cycles is configured to deposit a thickness of about 0.5 Å of the barrier layer 160.

In one or more embodiments, when the self-assembled monolayer (SAM) 150 is not present, the deposition of the barrier layer 160 is substantially conformal, such that the barrier layer 160 forms on the sidewalls 148 and the metal bottom 149 of the gap 146. According to one or more embodiments, as used herein, a layer which is “substantially conformal” refers to a layer where the thickness is about the same throughout (e.g., on the top, middle and bottom of sidewalls 148 and on the metal bottom 149 of the gap 146). A layer which is substantially conformal varies in thickness by less than or equal to about 5%, 2%, 1% or 0.5%.

In one or more embodiments, the barrier layer 160 is selectively deposited on a portion of the sidewalls 148 and does not form on the metal bottom 149 of the gap 146, due to the presence of the self-assembled monolayer (SAM) 150. In one or more embodiments, the barrier layer 160 does not cover the entirety of the sidewalls 148.

In one or more embodiments, when the self-assembled monolayer (SAM) 150 is present, the barrier layer 160 has a thickness in a range of from 5 Angstroms to 20 Angstroms on the sidewalls 148 and a thickness of less than or equal to 5 Angstroms on the metal bottom 149. In one or more embodiments, when the self-assembled monolayer (SAM) 150 is present, the barrier layer 160 has a thickness of less than or equal to 4 Angstroms, less than or equal to 3 Angstroms, less than or equal to 2 Angstroms, or less than or equal to 1 Angstrom on the metal bottom 149. In one or more embodiments, when the self-assembled monolayer (SAM) 150 is present, the barrier layer 160 does not form on the metal bottom 149.

The barrier layer 160 may comprise any suitable material that prevents copper from diffusing into the dielectric layer 145. Suitable barrier layers for copper barrier applications include, but are not limited to, tantalum nitride (TaN) and manganese nitride (MnN). In some embodiments, the barrier layer 160 comprises tantalum nitride (TaN) formed by atomic layer deposition (ALD). In some embodiments, ALD of the barrier layer 160 comprising tantalum nitride (TaN) includes exposing the substrate 110 to a tantalum-containing precursor, such as, for example, pentakis(dimethylamino)tantalum(V) (PDMAT) and a nitrogen-containing reactant, such as, for example, ammonia (NH₃).

In selective barrier applications and selective liner applications, the SAM selectively is deposited on the metal bottom 149 of the gap 146 as the self-assembled monolayer (SAM) 150. The metal bottom 149 comprises a metallic surface including, but not limited to, copper (Cu), cobalt (Co), tungsten (W), and/or molybdenum (Mo). The SAM advantageously suppresses subsequent deposition, e.g., provide nucleation delay on the metal bottom 149.

Referring to FIGS. 2A and 2D, at operation 15 of the method 10, the metal liner layer 170 is selectively deposited on the barrier layer 160 of FIG. 1B. In one or more embodiments, the metal liner layer 170 has the same properties as the metal layer 130. In one or more embodiments, the metal liner layer 170 is selectively deposited on the sidewalls 148 on the barrier layer 160. In one or more embodiments, the metal liner layer 170 does not form on the metal bottom 149 of the gap 146 due to the presence of the self-assembled monolayer (SAM) 150. At operation 15, the dielectric sidewalls may be treated with a plasma to remove carbon and oxygen impurities from the dielectric sidewalls.

In one or more embodiments, the metal liner layer 170 comprises one or more of ruthenium (Ru), cobalt (cobalt), molybdenum (Mo), or tantalum (Ta). In one or more embodiments, the metal liner layer 170 comprises one or more of a single layer of ruthenium (Ru) or a single layer of cobalt (Co). In one or more embodiments, the metal liner layer 170 comprises a single layer of ruthenium (Ru). In one or more embodiments, the metal liner layer 170 comprises a single layer of cobalt (Co). In one or more embodiments, the metal liner layer 170 comprises a single layer of ruthenium (Ru) that is selectively deposited on the sidewalls 148 and does not form on the metal bottom 149 of the gap 146 due to the presence of the self-assembled monolayer (SAM) 150.

In one or more embodiments, when the metal liner layer 170 comprises a single layer of ruthenium (Ru) selectively deposited on the sidewalls 148 and the self-assembled monolayer (SAM) 150 is formed on the metal bottom 149, there is a ratio of the thickness of the metal liner thickness on the sidewalls 148 to the thickness of the metal liner layer 170 thickness on the metal bottom 149, the ratio being greater than 3. In one or more embodiments, the ratio of the thickness of the metal liner thickness on the sidewalls 148 to the thickness of the metal liner thickness on the metal bottom 149 is greater than 4, greater than 5, greater than 6 or greater than 7. In one or more embodiments, the metal liner layer 170 does not form on the metal bottom 149 due to the presence of the self-assembled monolayer (SAM) 150.

In one or more embodiments, when the metal liner layer 170 comprises a single layer of selectively deposited ruthenium (Ru), the metal liner layer 170 has a thickness in a range of from 5 Angstroms to 20 Angstroms on the sidewalls 148. In one or more embodiments, when the metal liner layer 170 comprises a single layer of selectively deposited ruthenium (Ru), the metal liner layer 170 has a thickness of less than or equal to 5 Angstroms on the metal bottom 149. In one or more embodiments, when the metal liner layer 170 comprises a single layer of selectively deposited ruthenium (Ru), the metal liner layer 170 has a thickness of less than or equal to 4 Angstroms, less than or equal to 3 Angstroms, less than or equal to 2 Angstroms, or less than or equal to 1 Angstrom on the metal bottom 149. In one or more embodiments, the metal liner layer 170 does not form on the metal bottom 149 due to the presence of the self-assembled monolayer (SAM) 150.

In one or more embodiments, the metal liner layer 170 comprises a multilayer film having a first liner layer comprised of a first metal and a second liner layer comprised of a second metal. Each of the first metal and the second metal independently comprise one or more of ruthenium (Ru), cobalt (cobalt), molybdenum (Mo), or tantalum (Ta). In one or more embodiments, the first liner layer comprises ruthenium (Ru) and the second liner layer comprises cobalt (Co).

In one or more embodiments, when the metal liner layer 170 comprises the multilayer film having the first liner layer comprised of the first metal and the second liner layer comprised of the second metal, the multilayer film has a combined thickness in a range of 10 to 20 Angstroms on the sidewalls 148. In one or more embodiments, when the first liner layer comprises ruthenium (Ru) and the second liner layer comprises cobalt (Co), the multilayer film has a combined thickness in a range of 5 to 20 Angstroms on the metal bottom 149. In one or more embodiments, when the first liner layer comprises ruthenium (Ru) and the second liner layer comprises cobalt (Co), the multilayer film does not form on the metal bottom 149.

In some embodiments, the multilayer film comprises an alloy of the two metals in a single layer. In one or more embodiments, the multilayer film comprises an alloy of one or more of ruthenium (Ru), cobalt (cobalt), molybdenum (Mo), or tantalum (Ta), such as, for example, an alloy of ruthenium (Ru) and cobalt (cobalt), an alloy of ruthenium (Ru) and molybdenum (Mo), an alloy of ruthenium (Ru) and tantalum (Ta), an alloy of cobalt (cobalt) and molybdenum (Mo), or an alloy of cobalt (Co) and tantalum (Ta).

Referring to FIGS. 2A and 2E, at operation 15 of the method 10, the self-assembled monolayer (SAM) 150 is removed. In one or more embodiments, removing the self-assembled monolayer (SAM) 150 comprises a plasma treatment process. The plasma treatment process can be any suitable process. In one or more embodiments, the plasma treatment process includes a physical vapor deposition (PVD) process. In one or more embodiments, the plasma treatment comprises flowing one or more of hydrogen (H₂) or argon (Ar). In one or more embodiments, the plasma treatment process increases a density of the barrier layer 160. Further, at operation 16, embodiments of the method 10 include diffusing at least one of manganese and manganese nitride into the barrier/liner layer.

In FIG. 2E, diffused manganese and/or manganese nitride is shown as dotted line 165 within the barrier/liner 160/170 and the barrier layer 160. In the area where the self-assembled monolayer (SAM) 150 was located there is only a thin barrier/liner layer 160/170, and the diffused manganese and/or manganese nitried 165a fills the area that had been occupied by the self-assembled monolayer (SAM) 150. In one or more embodiments, diffusing at least one of manganese and manganese nitried into the barrier/liner layer prevents formation of a void between the metal bottom and the barrier/liner layer. In FIG. 2E., the barrier/liner layer 160/170 layer extends from the top 146T of the gap 146 to the bottom of the gap at the metal bottom 149, and the at least one of manganese and manganese nitride is diffused into the barrier layer from the top 146T of the gap 146 to the metal bottom 149 of the gap 146. In some embodiments, diffusing the at least one of manganese and manganese nitride comprises depositing at least one of a manganese layer and a manganese nitride layer using atomic layer deposition or chemical vapor deposition. In some embodiments, the atomic layer deposition or chemical vapor deposition is performed at a temperature in a range of 150 °C to 350 °C. In some embodiments, a conformal layer is formed on the barrier/liner layer.

Referring to FIGS. 2A and 2F, the method 10 includes depositing a metal film to fill the gap by performing a gap fill process to fill the gap 146 (operation 17). The gap fill process can include any suitable deposition technique. In one or more embodiments, the gap fill process comprises a physical vapor deposition (PVD) process. In one or more embodiments, the gap fill process comprises filling the gap 146 with a gap fill material 180. The gap fill material 180 may include any suitable material, such as a conductive material. In one or more embodiments, the gap fill material 180 comprises copper (Cu) or tungsten (W). In one or more embodiments, the gap fill process comprises filling the gap 146 with copper (Cu) or tungsten (W) by physical vapor deposition (PVD).

The gap fill material 180 is substantially free of seams and/or voids or free of seams and/or voids. As used in this regard, “substantially free” means that less than about 5%, including less than about 4%, less than about 3%, less than about 2%, less than about 1%, less than about 0.5%, and less than about 0.1% of the total composition of the gap fill material 180 an atomic basis, comprises seams and/or voids. Advantageously, in one or more embodiments, the gap fill material 180 is free of seams and/or voids. As can be seen in FIG. 2F, there is no void as shown in FIGS. 1A and 1B.

Referring now to FIGS. 2G and 2H, and alternate embodiment of method 10 is shown, particularly with respect to operation 16. In FIGS. 2G and 2H, the at least one of the manganese and manganese nitride is diffused into barrier/liner layer at only a portion of the barrier/liner layer adjacent to the metal bottom 149. This is accomplished in some embodiments by selectively depositing at least one of a manganese layer and a manganese nitride layer 166 on the metal bottom 149 after removing the self-assembled monolayer in operation 15. The at least one of the manganese and manganese nitride is diffused into barrier/liner layer is diffused from at least one of the manganese layer and the manganese nitride layer 166 on the metal bottom 149. Selectively depositing at least one of a manganese layer and a manganese nitride layer 166 on the metal bottom 149 may comprise atomic layer deposition or chemical vapor deposition. The atomic layer deposition or chemical vapor deposition is performed at a temperature in a range of 150 °C to 350 °C. The atomic layer deposition or chemical vapor deposition is performed at a pressure in a range of 1 Torr to 10 Torr. Then, the at least one of the manganese layer and the manganese layer 166 is annealed at a temperature in a range of 200 °C to 400 °C to drive at least one of manganese and manganese nitride 166a into the portion of the barrier/liner layer adjacent to the metal bottom 149.

In one or more embodiments, after filling the gap 146 with the gap fill material 180, a completed interconnect structure, e.g., interconnect structure 190 is formed, such that additional interconnect structures may be formed on top of or below the interconnect structure 190. Advantageously, the at least one of the manganese and the manganese nitride improves adhesion of the metal film to the barrier/liner layer. Further, the at least one of the manganese and the manganese nitride advantageously prevents delamination of the metal film.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of filling a gap defined by dielectric sidewalls and a metal bottom in a surface of a substrate, the method comprising:
depositing a self-assembled monolayer on the metal bottom of the gap;
depositing a barrier layer on the dielectric sidewalls that extends from a top of the gap to the metal bottom of the gap and does not cover the metal bottom of the gap;
depositing a liner layer on the barrier layer to provide a barrier/liner layer;
removing the self-assembled monolayer;
diffusing at least one of manganese and manganese nitride into the barrier/liner layer; and
depositing a metal film to fill the gap.

2. The method of claim 1, wherein diffusing at least one of manganese and manganese nitride into the barrier/liner layer prevents formation of a void between the metal bottom and the barrier/liner layer.

3. The method of claim 2, further comprising treating the dielectric sidewalls with a plasma after depositing the liner layer to remove carbon and oxygen impurities from the dielectric sidewalls.

4. The method of claim 3, wherein the barrier/liner layer extends from the top of the gap to the bottom of the gap, and the at least one of manganese and manganese nitride is diffused into the barrier layer from the top of the gap to the bottom of the gap.

5. The method of claim 3, wherein the barrier layer is doped with at least one of manganese and manganese nitride.

6. The method of claim 5, wherein diffusing the at least one of manganese and manganese nitride comprises depositing at least one of a manganese layer and a manganese nitride layer using atomic layer deposition or chemical vapor deposition.

7. The method of claim 6, wherein the atomic layer deposition or chemical vapor deposition is performed at a temperature in a range of 150 °C to 350 °C.

8. The method of claim 7, wherein the at least one of a manganese layer and a manganese nitride layer is a conformal layer.

9. The method of claim 8, wherein the at least one of the manganese layer and the manganese nitride layer improves adhesion of the metal film to the barrier/liner layer.

10. The method of claim 9, wherein the metal film comprises copper.

11. The method of claim 3, wherein the at least one of the manganese and manganese nitride is diffused into the barrier/liner layer at only a portion of the barrier/liner layer adjacent to the metal bottom.

12. The method of claim 11, further comprising selectively depositing at least one of a manganese layer and a manganese nitride layer on the metal bottom after removing the self-assembled monolayer.

13. The method of claim 12, wherein the at least one of the manganese and manganese nitride is diffused into the barrier/liner layer is diffused from at least one of the manganese layer and the manganese nitride layer on the metal bottom.

14. The method of claim 13, wherein selectively depositing at least one of a manganese layer and a manganese nitride layer on the metal bottom comprises atomic layer deposition or chemical vapor deposition.

15. The method of claim 14, wherein the atomic layer deposition or chemical vapor deposition is performed at a temperature in a range of 150 °C to 350 °C.

16. The method of claim 15, wherein the atomic layer deposition or chemical vapor deposition is performed at a pressure in a range of 1 Torr to 10 Torr.

17. The method of claim 16, further comprising annealing the at least one of the manganese layer and the manganese nitride layer at a temperature in a range of 200 °C to 400 °C to drive at least one of manganese and manganese nitride into the portion of the barrier/liner layer adjacent to the metal bottom.

18. The method of claim 16, wherein the at least one of the manganese and the manganese nitride improves adhesion of the metal film to the barrier/liner layer.

19. The method of claim 18, wherein the metal film comprises copper.

20. The method of claim 19, wherein the at least one of the manganese and the manganese nitride prevents delamination of the metal film.
